(19) United States
(12) Patent Application Publication
(10) Pub. No.: US 2011/0226419 A1
(43) Pub. Date: Sep. 22, 2011

(54) Process Chamber, Semiconductor Manufacturing Apparatus and Substrate Processing Method Having the Same

(76) Inventors: Yong Hyun Lee, Seongnam-si (KR); Myung Jin Lee, Gunpo-si (KR); An Ki Cha, (US)

(21) Appl. No.: 13/049,743

(22) Filed: Mar. 16, 2011

(30) Foreign Application Priority Data
Mar. 18, 2010 (KR) 10-2010-0024019
Aug. 17, 2010 (KR) 10-2010-0079066

(51) Int. Cl. H01L 21/677; H01L 21/306

(52) U.S. Cl. 156/345.31; 156/345.51; 414/806

(57) ABSTRACT

Disclosed herein is a semiconductor manufacturing apparatus including a transfer chamber provided with a substrate moving device to move substrates, a load lock chamber to align the substrates and to load and unload the substrates into and out of the transfer chamber, and at least one process chamber to process the substrates transferred from the transfer chambers. Each of the at least one process chamber includes a chamber body provided with a substrate entrance formed on a side surface thereof, a substrate support provided within the chamber body such that at least two substrates are disposed on the substrate support, and at least one divider provided within the chamber body to align the at least two substrates.

This application claims the benefit of Korean Patent Application No. 10-2010-0024019, filed on Mar. 18, 2010 and 10-2010-0079066 filed on Aug. 17, 2010, which are hereby incorporated by reference as if fully set forth herein.

### BACKGROUND OF THE INVENTION

1. Field of the Invention

The present invention relates to a semiconductor manufacturing apparatus, and more particularly, to a process chamber to process substrates, such as semiconductor devices, and an apparatus and method to transfer the substrates between chambers.

2. Discussion of the Related Art

In general, in order to manufacture semiconductor devices, flat display devices and solar cells, a thin film deposition process in which a thin film formed of a specific material is deposited on the surface of a wafer or glass, a photolithography process in which selected regions of the thin film are exposed or shielded using a photosensitive material, and an etching process in which the thin film is desirably patterned by removing the thin film from the selected regions are required.

Further, in order to perform the above processes, the thin film deposition process, the etching process, etc. are respectively carried out in a plurality of process chambers. Transfer of substrates between the plural process chambers is carried out via a transfer chamber.

The above conventional process chambers and a semiconductor manufacturing apparatus having the same have problems, as follows.

Each of the respective process chambers processes one substrate. Therefore, after one substrate is transferred to one process chamber and the substrate is processed under a vacuum atmosphere in the process chamber, the substrate must be transferred to another process chamber. Thereby, productivity is lowered.

That is, whenever one substrate is transferred to one process chamber, the process chamber needs to be operated, and whenever one substrate enters or exits the process chamber, an entrance of the process chamber needs to be opened and closed and the vacuum atmosphere in the process chamber needs to be formed again.

### SUMMARY OF THE INVENTION

Accordingly, the present invention is directed to a process chamber, a semiconductor manufacturing apparatus and a substrate processing method having the same.

An object of the present invention is to provide a process chamber to process substrates, such as semiconductor devices, and an apparatus and method to transfer the substrates between chambers.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims thereof as well as the appended drawings.

To achieve these objects and other advantages and in accordance with the purpose of the invention, as embodied and broadly described herein, a process chamber includes a chamber body provided with a substrate entrance formed on a side surface thereof, a substrate support provided within the chamber body such that at least two substrates are disposed on the substrate support, and at least one divider provided within the chamber body to align the at least two substrates.

Each of the at least one divider may include a support member to support parts of the edges of the at least two substrates and a separation member contacting the at least two substrates to separate the at least two substrates from each other.

The at least one divider may include a divider having a rectilinear shape to divide and align a pair of substrates facing each other, or include two dividers having a rectilinear shape which cross each other to divide and align four substrates.

The at least one divider may have a line width of 4˜60 mm.

The at least one divider may align the at least two substrates at the same height.

The at least one divider may be formed of a ceramic or anodizing coated aluminum.

The substrate support may include at least one of a loading frame to support the outermost regions of the lower surfaces of the at least two substrates and pins to support the central regions of the lower surfaces of the at least two substrates.

In another aspect of the present invention, a semiconductor manufacturing apparatus includes a transfer chamber provided with a substrate moving device to move substrates, a load lock chamber to align the substrates and to load and unload the substrates into and out of the transfer chamber, and at least one process chamber to process the substrates transferred from the transfer chambers, wherein each of the at least one process chamber includes a chamber body provided with a substrate entrance formed on a side surface thereof, a substrate support provided within the chamber body such that at least two substrates are disposed on the substrate support, and at least one divider provided within the chamber body to align the at least two substrates.

The semiconductor manufacturing apparatus may further include alignment members provided in the load lock chamber to align the substrates.

The alignment members may be provided at least two corners of a support on which the substrates are seated.

Two substrates facing each other may be provided within the load lock chamber, and the alignment members may include stationary members or rotary members provided between the two substrates.

Four substrates may be provided within the load lock chamber, and the alignment members may include a pair of alignment members having a rectangular shape, crossing each other and provided at the center of the four substrates where the four substrates meet.

The pair of alignment members may include at least four rotary members respectively provided between the four substrates and the four substrates are aligned by rotation of the rotary members.

The alignment members within the load lock chamber and the at least one divider within the process chamber may align the substrates in the same pattern.

In a further aspect of the present invention, a substrate processing method includes sequentially loading at least two substrates into a first chamber provided with alignment members, aligning corners of the at least two substrates using the alignment members, conveying the at least two substrates from the first chamber to a second chamber using a substrate conveyor unit, and conveying the at least two substrates from the second chamber to a third chamber using the substrate conveyor unit, wherein the at least two substrates are loaded in the third chamber in the same pattern as an aligned pattern of the at least two substrates within the first chamber.

At least one divider may divide and align the at least two substrates at the same height by a predetermined interval within the third chamber.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1A to 1F are views illustrating process chambers in accordance with embodiments of the present invention;

FIGS. 2A and 2B are views illustrating substrates loaded on a substrate support of FIG. 1A;

FIG. 3 is a view illustrating a semiconductor manufacturing apparatus in accordance with one embodiment of the present invention;

FIG. 4 is a view illustrating alignment of substrates in a load lock chamber of FIG. 3;

FIGS. 5A to 5F are views illustrating alignment members of FIG. 4 in accordance with embodiments of the present invention;

FIGS. 6 and 7 are views illustrating a substrate moving device in accordance with one embodiment of the present invention; and

FIG. 8 is a view illustrating a semiconductor manufacturing apparatus in accordance with another embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

In the accompanying drawings, the thicknesses of several layers and regions are exaggerated for clarity. A thickness ratio between the respective layers in the drawings does not represent an actual thickness ratio.

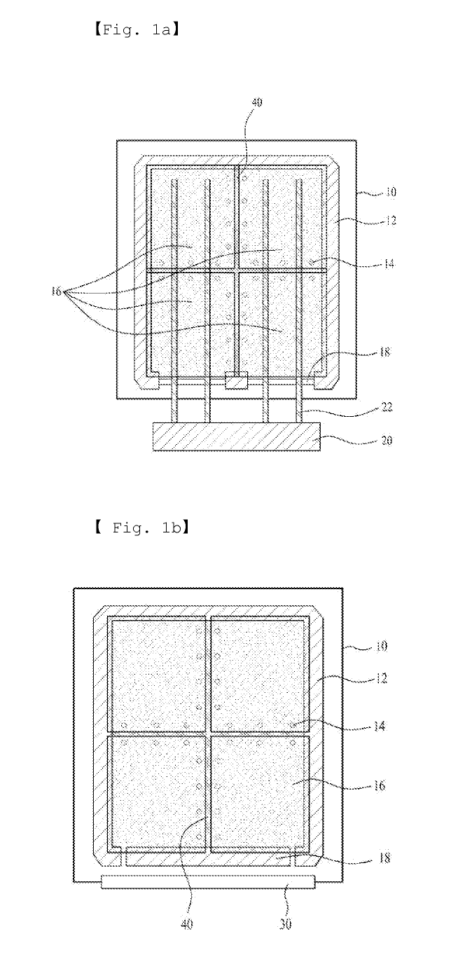

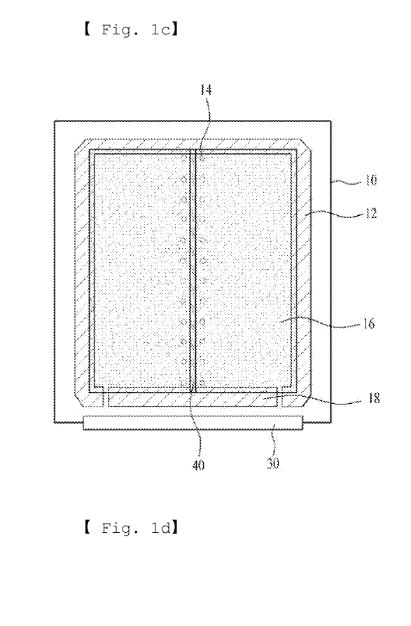

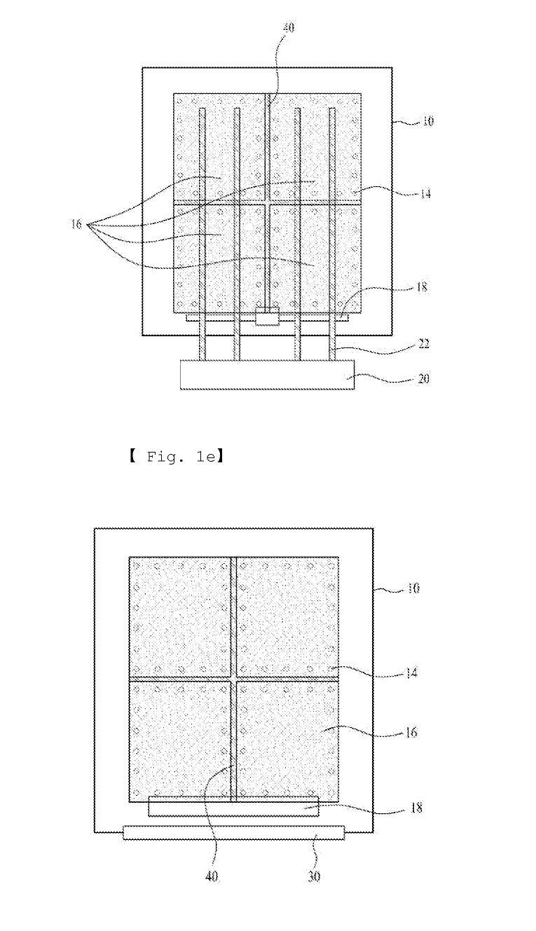

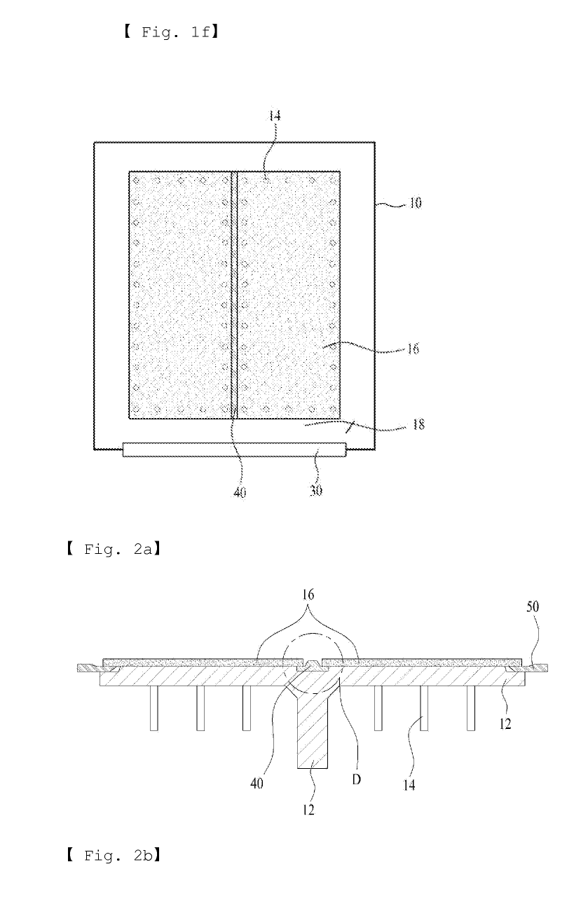

FIGS. 1A to 1F are views illustrating process chambers in accordance with embodiments of the present invention and FIGS. 2A and 2B are views illustrating substrates loaded on a substrate support of FIG. 1A. Hereinafter, a process chamber in accordance with one embodiment of the present invention will be described with reference to FIG. 1A and FIGS. 2A and 2B.

In this embodiment, a plurality of substrates 16 is simultaneously loaded in the process chamber, and a process, such as deposition of a semiconductor layer on the plurality of substrates 16, is carried out at one time.

FIG. 1A illustrates the inside of the process chamber, and four substrates 16 are provided in a chamber body 10. Here, the respective substrates 16 are loaded on a substrate support within the chamber body 10.

The substrate support includes a loading frame 12 and pins 14. The loading frame 12 supports surfaces of the respective substrates 16 facing the chamber body 10. That is, assuming that the four substrates 16 are regarded as one substrate, the loading frame 12 supports the edge of the substrate.

Further, the pins 14 support the edge of the respective substrates 16 facing dividers 40. That is, if the respective substrates 16 have a rectangular cross-section, two sides of each of the substrates 16 facing the chamber body 10 are supported by the loading frame 12 and the remaining two sides of each of the substrates 16 are supported by the pins 14.

The substrates 16 may be supported by the loading frame 12 alone or the pins 14 alone. Here, the loading frame 12 or the pins 14 need to be provided so as to support all the edges of the four substrates 16.

Further, the four substrates 16 are divided by the dividers 40. Here, if the four substrates 16 are provided in the process chamber, the dividers 40 are provided such that the dividers 40 having a rectilinear shape cross each other so as to divide the four substrates 16 from each other. That is, when the dividers 40 divide the four substrates 16, the dividers 40 are formed in a shape similar to a cross.

FIG. 2A illustrates the substrates 16 loaded on the substrate support 12 and 14 of FIG. 1A. The substrates 16 are supported by a susceptor 50, and the loading frame 12 supports only the edges of the substrates 16.

FIG. 2B is an enlarged view of the portion D of FIG. 2A.

The dividers 40 divide and align the substrates 16 while directly contacting the substrates 16. Each of the dividers 40 includes a support member 40a and a separation member 40b. The support member 40a supports parts of the edges of the substrates 16 and the separation member 40b separates the substrates 16 from each other so that the neighboring substrates 16 do not contact each other. Here, the separation member 40b has a trapezoidal shape, and reduces an area directly contacting the substrates 16 while separating the substrates 16 from each other, thereby preventing damage to the substrates 16.

Here, the neighboring substrates 16 are separated from each other at least by a width T₁ of the lower side of the separation member 40b. In this embodiment, the neighboring substrates 16 are separated from each other by 4˜60 mm. That is, if the divider 40 has a bilaterally symmetrical structure, the substrates 16 are separated from the center of the divider 40 by at least 2˜30 mm, thereby preventing interference generated between the respective substrates 16 in the process chamber.

Further, since the substrates 16 are supported by the support member 40a of the same divider 40, the substrates 16 may be supported at the same height.

That is, since a margin allowing the neighboring substrates 16 to be loaded on a robot is 4 mm, if the separation member 40b of the divider 40 has a width of less than 4 mm, the neighboring substrates 16 collide with each other due to lack of the margin, when the substrates 16 are loaded on the susceptor 50, thus being damaged. Further, the area of part of the substrates 16 loaded on the dividers 40 is increased, and the parts of the substrates 16 loaded on the dividers 40 are made of an ungrounded insulator, and thus uniformity of a thin film formed on the substrates 16 may be lowered.

Further, for example, during a thin film deposition process, the separation member 40b of the divider 40 allows the thin film formed on the neighboring substrates 16 not to be connected and prevents the susceptor 50 supporting the substrates 16 from being exposed to plasma, thereby allowing a desired thickness of the thin film to be deposited on the substrates 16.

On the other hand, if the separation member 40b of the divider 40 has a width of more than 60 mm, space utility is not sufficient in consideration of the restricted space within the chamber body 10. That is, when a line width of the dividers 40 is increased, the area of the susceptor 50 is also increased.

Further, when the line width of the separation members 40b of the dividers is increased, the substrates 16 may be loaded on the susceptor 50 alone. In this case, when the susceptor 50 are exposed to plasma, arcing of the susceptor 50 may occur, and the plasma may be deposited on the susceptor 50 and thus the substrates 16 may not be effectively aligned during subsequent substrate processing.

Preferably, the dividers 40 do not react with plasma and an etchant during processes, such as the thin film deposition process and the etching process. In this embodiment, the dividers 40 are formed of an insulator, such as a ceramic or anodizing coated aluminum. Since the susceptor 50 is grounded, when the area of the dividers 40 formed of the insulator is increased, the area of regions in which plasma is not generated is increased. Thus, generated lower plasma density is achieved and uniformity of the thin film to be formed may be lowered.

Since the dividers 40 have only a height enough to exhibit the above-described effects, the separation members 40b of the dividers 40 may have a difference of ±10 mm or less with a height of the neighboring substrates 16.

FIG. 1B illustrates the process chamber in accordance with the embodiment shown in FIG. 1A under the condition that the chamber body 10 is closed after the substrates 16 are loaded in the chamber body 10. That is, FIG. 1A illustrates the process chamber in which arms 22 of a substrate conveyor unit 20 transfer the substrates 16 to the inside of the chamber body 10, and FIG. 1B illustrates the process chamber in which a valve 30 closes the chamber body 10 after the substrates 16 are loaded on the substrate support.

Here, the valve 30 includes a valve housing and a blade moving in the valve housing to open and close an opening on the valve housing.

The process chamber in accordance with another embodiment shown in FIG. 1C is similar to the process chamber in accordance with the former embodiment of FIG. 1B except that two substrates 16 are loaded in one chamber body 10 of the process chamber in accordance with this embodiment of FIG. 1C. As shown in FIG. 1C, one divider 40 having a rectilinear shape so as to divide the two substrates 16 from each other is provided. A line width and a height of the divider 40 is the same as those of the dividers 40 in accordance with the former embodiment. Surfaces of the two substrates 16 facing each other are supported by pins 14, in the same manner as the former embodiment.

FIGS. 1D to 1E illustrate a process chamber in accordance with another embodiment in which substrates 16 are supported by pins 14 alone without the loading frame 12 shown in FIGS. 1A to 1C.

That is, FIG. 1D illustrates the process chamber in which the pins 14 are provided along the edges of the respective substrates 16 in a chamber body 10 so as to support the substrates 16, and FIG. 1E illustrates the process chamber in which the chamber body 10 is closed after the substrates 16 are loaded on the chamber body 10 of FIG. 1D.

Further, FIG. 1F illustrates a process chamber in accordance with another embodiment in which two substrates 16 are provided in one chamber body 10 and pins 14 supports the edges of the respective substrates 16. That is, assuming that the process chamber is a chamber having a size of 8.5 G (2,200 mm * 2,600 mm), which can enable processing of large substrates, used in a plasma enhanced chemical vapor deposition (PECVD), the process chamber in accordance with the embodiment shown in FIG. 1A may load and process four substrates having a size of 5 G (1,100 mm * 1,300 mm) at a time, and the process chamber in accordance with the embodiment shown in FIG. 1C may load and process two larger substrates at a time.

Further, the process chambers in accordance with above embodiments may load and process other substrates having different sizes and provided in different numbers from those of the above substrates at a time. Here, the dividers 40 may be provided so as to divide or isolate the respective substrates from each other.

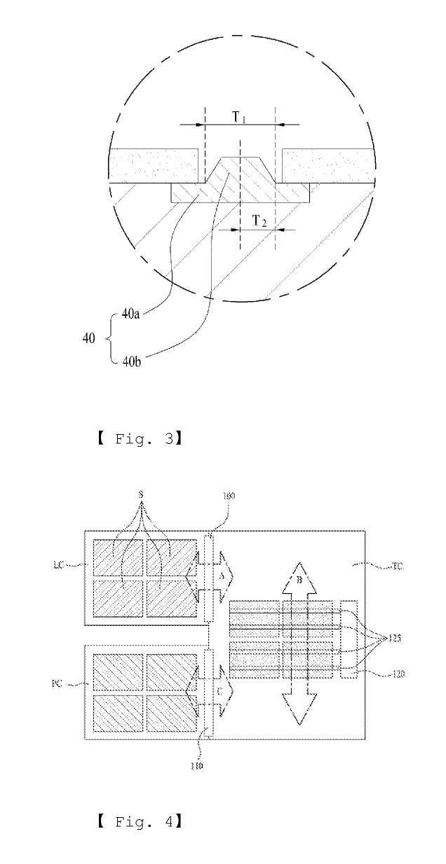

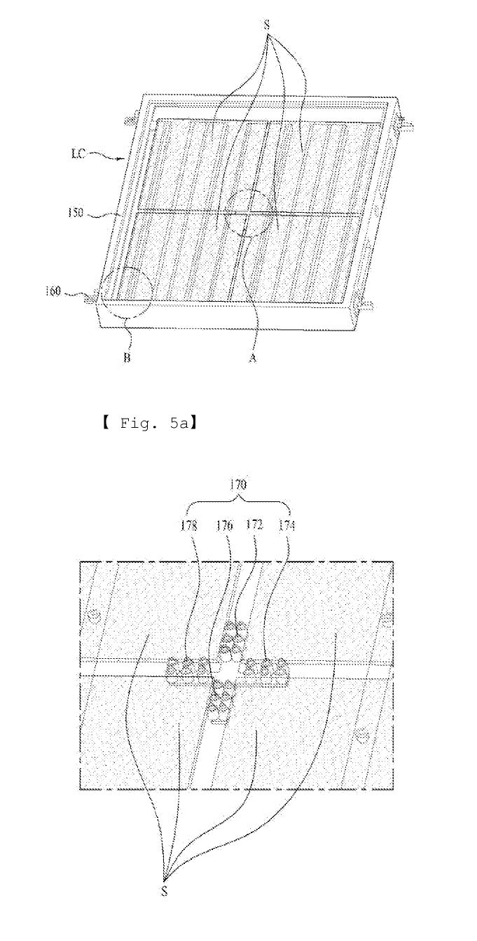

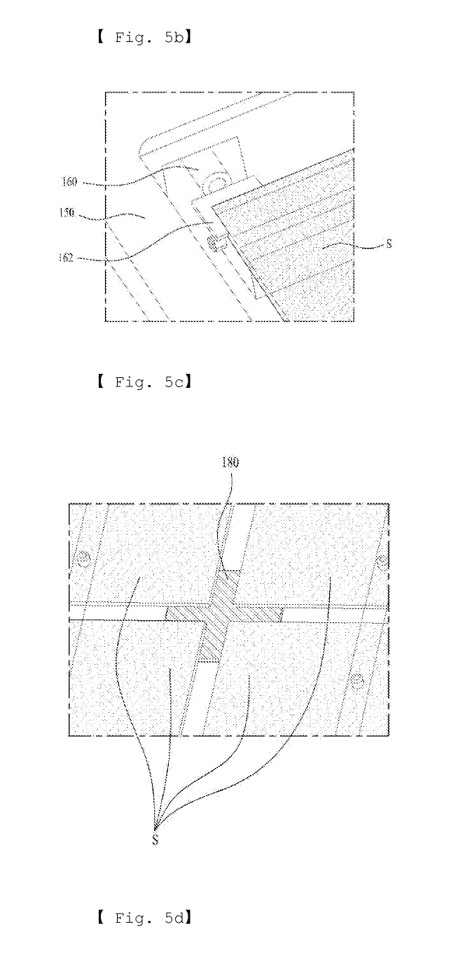

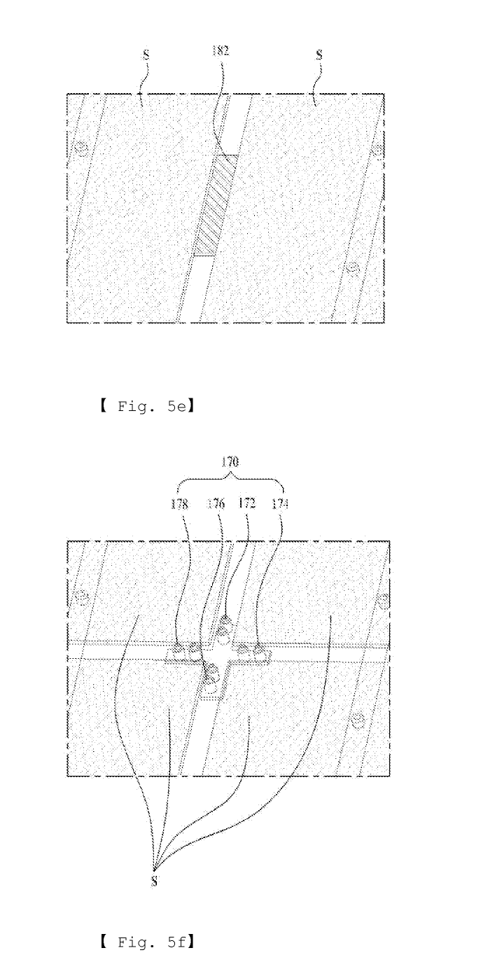

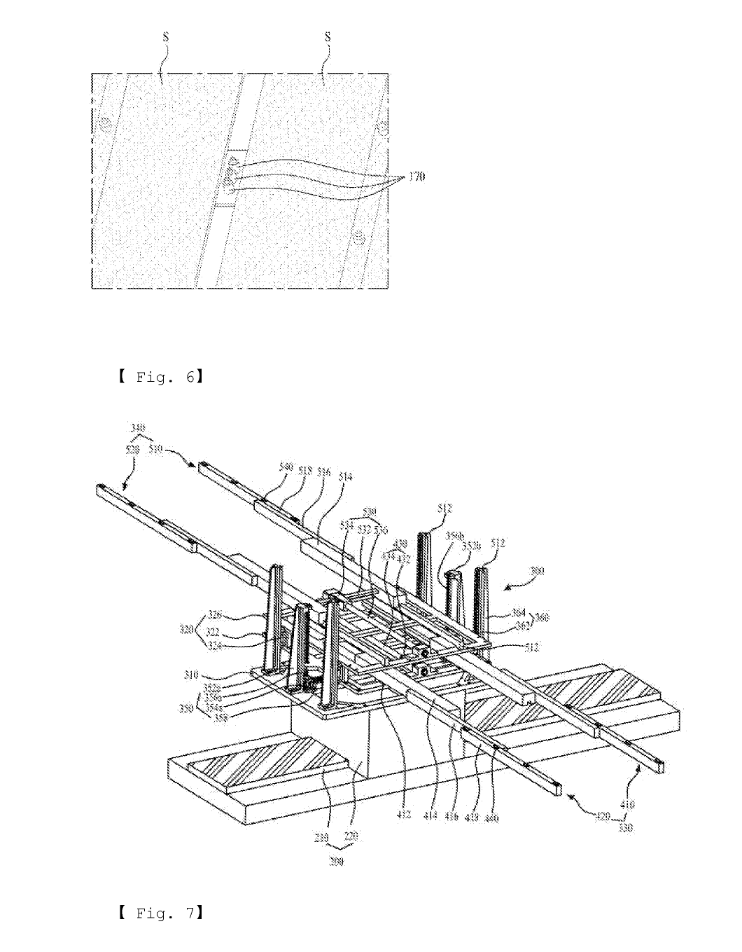

FIG. 3 is a view illustrating a semiconductor manufacturing apparatus in accordance with one embodiment of the present invention, FIG. 4 is a view illustrating alignment of substrates in a load lock chamber of FIG. 3, and FIGS. 5A to 5F are views illustrating alignment members of FIG. 4 in accordance with embodiments of the present invention. Hereinafter, the semiconductor manufacturing apparatus in accordance with this embodiment will be described with reference to FIGS. 3 to 5F.

The semiconductor manufacturing apparatus in accordance with this embodiment includes the above-described process chamber. That is, the semiconductor manufacturing apparatus includes a load lock chamber LC, a transfer chamber TC, and the process chamber PC, and gates 100 and 110 are provided between the respective chambers.

The load lock chamber LC loads substrates S from the outside into the transfer chamber TC, and unloads substrates supplied from the transfer chamber TC to the outside. Further, the transfer chamber TC is provided with a substrate moving device 120 to move substrates S within the transfer chamber TC, thereby transferring the substrates S to other chambers. Here, arms 125 connected to the substrate moving device 120 support the substrates S during fixing and transferring of the substrates S.

More specifically, the process chamber PC has the same configuration as the process chamber in accordance with the embodiment of FIG. 1A and FIGS. 2A and 2B. That is, the process chamber PC includes a chamber body provided with a substrate entrance formed on one side surface thereof, and dividers provided in the chamber body to divide plural substrates from each other, and performs processing of the substrates.

Therefore, the dividers in the process chamber PC having a rectilinear shape cross each other so as to divide the four substrates from each other, and are formed of a ceramic or anodizing coated aluminum.

Further, the process chamber PC includes a substrate supporter including a loading frame to support surfaces of the substrates facing the chamber body and pins to support surfaces of the substrates facing the dividers in the same manner as the process chamber in accordance with the embodiment of FIG. 1A and FIGS. 2A and 2B.

Alignment members are provided in the load lock chamber LC, thus performing alignment of the substrates S. That is, when the substrates are supplied from the outside to the load lock chamber LC, the load lock chamber LC performs alignment of the substrates S using the alignment members and then supplies the substrates to the transfer chamber TC.

That is, when four substrates S are supplied to the process chamber PC, the four substrates S must be aligned by the dividers and be then loaded. However, alignment of the substrates S within the process chamber PC is not desirable in view of process efficiency, and opening of the process chamber PC for a long time is not desirable in consideration of a subsequent deposition process.

Here, the process chamber PC may perform processes, such as a deposition process, a washing process, a preliminary heating process, a drying process, a heat treatment process, a photolithography process, an etching process, a diffusion process and an ion implantation process, on the respective substrates S transferred from the transfer chamber TC. As will be described later, a plurality of process chambers may be provided.

Therefore, the load lock chamber LC aligns the substrates S and then supplies the substrates S to the transfer chamber TC in the direction A, and the transfer chamber TC supplies the substrates T to the process chamber in the direction C.

Here, the substrates S within the transfer chamber TC may horizontally move in the direction B. The transfer chamber TC itself does not move but the substrate moving device 120 and the arms 125 move so as to move the substrates S.

That is, as shown in FIG. 3, the substrate moving device 120 may move in the direction B and the arms 125 may move in the direction A and the direction C. Further, although FIG. 3 illustrates one process chamber PC alone, an array of process chambers PC may be provided so as to continuously perform plural processes and such a structure will be described later with reference to FIG. 8.

FIG. 4 is a view illustrating the inside of the load lock chamber LC to display alignment of the substrates S in detail.

In FIG. 4, the load lock chamber LC includes a body 150 in which the substrates S are provided, and the alignment members to align the substrates S. Here, four substrates S are provided within the load lock chamber LC, and the substrates S are aligned at the center A or the edge of the load lock chamber LC.

That is, the alignment members align the substrates S at the center A of the load lock chamber LC, as shown in FIGS. 5A, 5C and 5D, or align the substrates S at the edge B of the load lock chamber LC, as shown in FIG. 5B. Such two types of alignment members may be selectively provided or be simultaneously provided.

Further, the alignment members may include stationary members or rotary members. FIGS. 5A, 5E and 5F illustrate rollers as the rotary members, and FIGS. 5B, 5D, and 5E illustrate rectilinear alignment members as the stationary members. Here, the rotary members, such as the rollers, contact the substrates S and move the substrates S using frictional force due to rotation, thus being capable of aligning the substrates S.

FIG. 5A illustrates alignment members 170 provided at the center of the load lock chamber LC. As shown in FIG. 5A, the alignment members 170 are provided at a point where the four substrates S meet. Here, the alignment members 170 are provided at regions where the edges of the respective substrates S come into plane contact with each other. In this embodiment, four alignment members 172, 174, 176 and 178 are provided at the point where the four substrates S meet.

The respective alignment members 172, 174, 176 and 178 may have a size (diameter) of 4˜60 mm, and such a size may be the same as the line width of the separation members of the dividers in the process chamber.

In FIG. 5A, each of the respective alignment members 172, 174, 176 and 178 include a plurality of circular rollers. The above-described size of 4˜60 mm represents the separation distance between the neighboring substrates S. The alignment members 172, 174, 176 and 178 including the circular rollers serve to precisely align the substrates S through rotation and friction of the alignment members 172, 174, 176 and 178 at points where the alignment members 172, 174, 176 and 178 come into plane contact with the respective substrates S.

FIGS. 5C and 5D illustrate alignment members in accordance with other embodiments of the present invention. In FIG. 5C, a pair of alignment members 180 having a rectilinear shape cross each other at the center of the load lock chamber LC where four substrates S meet, similarly to the dividers in the process chamber. Here, a line width of the alignment members 180 may be 4˜60 mm.

However, the alignment members in the load lock chamber LC serve to align the substrates, and thus adjust only the interval between the substrates S at the center of the substrates S without coming into plane contact with the all the edges of the substrates S differently from the dividers in the process chamber PC.

In FIG. 5D, two substrates S are provided in one chamber, and thus one alignment member 182 having a rectilinear shape is provided.

FIG. 5B illustrates an alignment member 162 to align the substrate S at the edge B of the load lock chamber LC, as shown in FIG. 4. With reference to FIG. 5B, the alignment member 162 surrounds the edge of the substrate S and operation of the alignment member 162 is controlled by a fine adjusting device 160.

The alignment members shown in FIG. 5A control the substrates S so that the neighboring substrates S are not excessively close to each other, and the alignment members 162 of FIG. 5B controls the substrates S so that the substrates S are not excessively distant away from each other. Here, it will be appreciated that the alignment member 162 of FIG. 5B is provided at corners of the respective substrates S.

Further, FIG. 5E illustrates alignment members 172, 174, 176 and 178 including circular rollers in accordance with another embodiment of the present invention. Differently from the embodiment of FIG. 5A, this embodiment illustrates that two rollers are disposed in each of lines.

Further, in FIG. 5F, two substrates S are provided in one chamber, and thus alignment members 170 including rollers is provided. The substrates S aligned by the above-described alignment members in the load lock chamber LC may be transferred to the process chamber PC through the transfer chamber TC. Here, the substrates S are transferred to the process chamber TC in the same pattern as in the load lock chamber LC.

The above-described transfer of the substrates between the chambers is carried out by the substrate moving device. The substrate moving device includes a substrate transfer unit to transfer the substrates in the horizontal direction and a substrate conveyor unit to convey the substrates to the load lock chamber and the process chamber through sliding.

Here, the substrate transfer unit may move the substrates in the direction B of FIG. 3. Further, the substrate conveyor unit may move the substrates in the direction A or in the direction C of FIG. 3. That, the substrate transfer unit and the substrate conveyor unit may move the substrates in directions perpendicular to each other, respectively.

The substrate conveyor unit may include a vertical moving part and a horizontal moving part. That is, the horizontal moving part slides the substrates in the direction A or in the direction C through sliding of the arms.

Further, the vertical moving part is in charge of loading and unloading of the substrates. In order to prevent damage to the edges of the substrates due to contact with the dividers when the substrates are loaded into or unloaded out of the process chamber, the vertical moving part raises or lowers the substrates after the horizontal moving part horizontally moves the substrates to the optimum position.

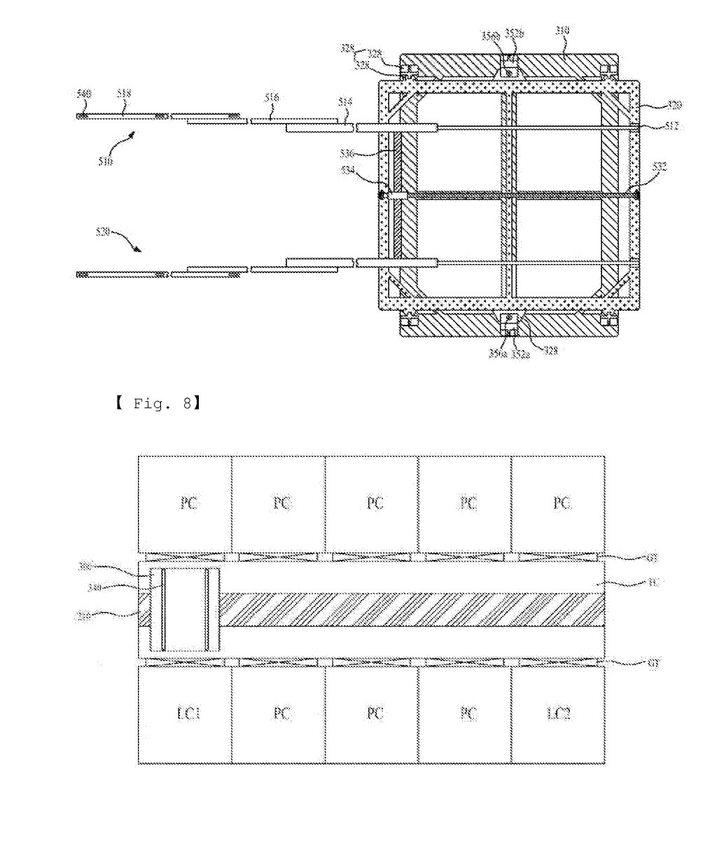

FIG. 8 is a view illustrating a semiconductor manufacturing apparatus in accordance with another embodiment of the present invention and FIGS. 6 and 7 are views illustrating the substrate moving device of FIG. 3.

In the semiconductor manufacturing apparatus in accordance with the embodiment of FIG. 3, the transfer chamber TC performs transfer of substrates between one load lock chamber LC and one process chamber PC. On the other hand, the semiconductor manufacturing apparatus in accordance with this embodiment of FIG. 8 includes a transfer chamber TC provided among a plurality of process chambers PC.

Therefore, transfer of substrates between different process chambers of FIG. 8 corresponds to transfer of substrates in the direction A or in direction C of FIG. 3, and transfer of the substrates by a transfer guide 210 in the horizontal direction of FIG. 8 corresponds to transfer of the substrates in the direction B of FIG. 3.

Here, a substrate moving device includes a substrate transfer unit 200 and a substrate conveyor unit 300. The substrate transfer unit 200 is installed in the longitudinal direction of the transfer chamber TC, and thus moves the substrate conveyor unit 300 in the horizontal direction. For this purpose, the substrate transfer unit 200 may be a linear motor.

Further, the substrate transfer unit 200 includes a transfer guide 210 and a transfer block part 220. The transfer guide 210 guides horizontal transfer of the transfer block part 220. For example, the transfer guide 210 may be a stator of the linear motor.

The transfer block part 220 is installed on the transfer guide 210 so as to be transferable, and is thus transferred in the horizontal direction along the transfer guide 210. For example, the transfer block part 220 may be a rotor (or a coil part) of the linear motor.

The substrate conveyor unit 300 includes a base frame 310, a fork frame 320, first and second bi-directional sliding fork units 330 and 340, a fork elevation unit 350, and a fork elevation guide unit 360.

The base frame 310 is installed on the transfer block part 220 of the substrate transfer unit 200, and is moved in the horizontal direction together with the transfer block part 220.

The fork frame 320 includes a first support frame 322, a plurality of side wall supports 324, and a second support frame 326.

The first support frame 322 is installed on the base frame 310 to a designated height and is supported by the fork elevation unit 350 so as to be raised and lowered. Protrusions 328 through which the fork elevation unit 350 passes are formed on first and second side surfaces of the first support frames 322.

The plural side wall supports 324 are installed at designated intervals along the edge of the first support frame 322, thus supporting the second support frame 326.

The second support frame 326 is installed on the plural side wall supporters 324 so as to overlap with the first support frame 322. The second support frame 326 is raised and lowered together with raising and lowering of the first support frame 322.

The first bi-directional sliding fork unit 330 in accordance with one embodiment includes first and second sliding forks 410 and 420, a first fork slider 430, and a plurality of first substrate support pads 440.

The first and second sliding forks 410 and 420 are installed at a designated interval in parallel on the first support frame 322, and are transferred in a first horizontal direction or a second horizontal direction opposite to the first horizontal direction according to driving of the first fork slider 430. Each of the first and second sliding forks 410 and 420 includes a first guide block 412 and first to third sliding bars 414, 416 and 418.

The first guide blocks 412 of the first and second sliding forks 410 and 420 are installed on the first support frame 322 between both sides of the first support frame 322, and guide sliding of the first sliding bars 414.

The first sliding bars 414 of the first and second sliding forks 410 and 420 are installed on the first guide blocks 412, and are transferred in the first horizontal direction or the second horizontal direction opposite to the first horizontal direction according to driving of the first fork slider 430.

The second sliding bars 416 of the first and second sliding forks 410 and 420 are installed on side surfaces of the first sliding bars 414, and are transferred in the horizontal direction in connection with sliding of the first sliding bars 414.

The third sliding bars 418 of the first and second sliding forks 410 and 420 are installed on side surfaces of the second sliding bars 416, and are transferred in the horizontal direction in connection with sliding of the second sliding bars 416.

On the other hand, the second and third sliding bars 416 and 418 may be sequentially stacked on the upper surfaces of the first sliding bars 414, and be transferred in the horizontal direction in connection with sliding of the first sliding bars 414.

The first fork slider 430 is installed between both sides of the first support frame 322 so as to be disposed between the first and second sliding forks 410 and 420, thus simultaneously transferring both the first and second sliding forks 410 and 420 in the first horizontal direction or the second horizontal direction opposite to the first horizontal direction.

The first fork slider 430 includes a first guide rod 432 installed between both sides of the first support frame 322 so as to be supported by a bracket, and a first transfer cylinder 434 installed on the first guide rod 432 so as to be transferable and provided with links (not shown) respectively connected to the first and second sliding forks 410 and 420. Such a first fork slider 430 may be a hydraulic or pneumatic cylinder to transfer the first transfer cylinder 434 using hydraulic pressure or pneumatic pressure supplied to at least one side surface of the first guide rod 432.

The plural first substrate support pads 440 are installed on the third sliding bars 418 at designated intervals, and support rear surfaces of substrates when the substrates are conveyed.

Although this embodiment describes the first bi-directional sliding fork unit 330 as including two sliding forks 410 and 420, the structure of the first bi-directional sliding fork unit 330 is not limited thereto and the first bi-directional sliding fork unit 330 may include two or more sliding forks so as to achieve stable substrate conveyance. Further, although this embodiment describes the first fork slider 430 of the first bi-directional sliding fork unit 330 as being the hydraulic or pneumatic cylinder, the first fork slider 430 is not limited thereto and the sliding forks 410 and 420 may be slid by at least one of an LM guider, a ball screw and a belt or combinations of at least two thereof.

The first bi-directional sliding fork unit 330 may further include a position sensor to detect sliding positions of the sliding bars 414, 416 and 418 so as to control the first fork slider 430 when the sliding bars 414, 416 and 418 are slid in both directions.

As described above, the first and second sliding forks 410 and 420 of the first bi-direction sliding fork unit 330 are stretched or retracted so as to be simultaneously slid in the first conveyance direction or the second conveyance direction opposite to the first conveyance direction using the first slider 430, thereby transferring the substrates to the process chamber PC disposed at one side or the other side of the transfer chamber TC in both directions.

The second bi-directional sliding fork unit 330 in accordance with this embodiment includes third and fourth sliding forks 510 and 520, a second fork slider 530, and a plurality of second substrate support pads 540.

The third and fourth sliding forks 510 and 520 are installed at a designated interval in parallel on the second support frame 326, and are transferred in the first horizontal direction or the second horizontal direction opposite to the first horizontal direction according to driving of the second fork slider 530. For this purpose, each of the third and fourth sliding forks 510 and 520 includes a second guide block 512 and fourth to sixth sliding bars 514, 516 and 518.

The second guide blocks 512 of the third and fourth sliding forks 510 and 520 are installed on the second support frame 326 between both sides of the second support frame 326, and guide sliding of the fourth sliding bars 514.

The fourth sliding bars 514 of the third and fourth sliding forks 510 and 520 are installed on the second guide blocks 512, and are transferred in the first horizontal direction or the second horizontal direction opposite to the first horizontal direction according to driving of the second fork slider 530.

The fifth sliding bars 516 of the third and sixth sliding forks 510 and 520 are installed on side surfaces of the fourth sliding bars 514, and are transferred in the horizontal direction in connection with sliding of the fourth sliding bars 514.

The sixth sliding bars 518 of the fourth and sixth sliding forks 510 and 520 are installed on side surfaces of the fifth sliding bars 516, and are transferred in the horizontal direction in connection with sliding of the fifth sliding bars 516.

On the other hand, the fifth and sixth sliding bars 516 and 518 may be sequentially stacked on the upper surfaces of the fourth sliding bars 514, and be transferred in the horizontal direction in connection with sliding of the fourth sliding bars 514.

The second fork slider 530 is installed between both sides of the second support frame 326 so as to be disposed between the third and fourth sliding forks 510 and 520, thus simultaneously transferring both the third and fourth sliding forks 510 and 520 in the first horizontal direction or the second horizontal direction opposite to the first horizontal direction.

The second fork slider 530 includes a second guide rod 532 installed between both sides of the second support frame 326 so as to be supported by a bracket, and a second transfer cylinder 534 installed on the second guide rod 532 so as to be transferable and provided with links 536 respectively connected to the third and fourth sliding forks 510 and 520. Such a second fork slider 530 may be a hydraulic or pneumatic cylinder to transfer the second transfer cylinder 534 using hydraulic pressure or pneumatic pressure supplied to at least one side surface of the second guide rod 532.

The plural second substrate support pads 540 are installed on the sixth sliding bars 518 at designated intervals, and support rear surfaces of substrates when the substrates are conveyed.

Although this embodiment describes the second bi-directional sliding fork unit 340 as including two sliding forks 510 and 520, the structure of the second bi-directional sliding fork unit 340 is not limited thereto and the second bi-directional sliding fork unit 340 may include two or more sliding forks so as to achieve stable substrate conveyance. Further, although this embodiment describes the second fork slider 530 of the second bi-directional sliding fork unit 340 as being the hydraulic or pneumatic cylinder, the second fork slider 530 is not limited thereto and the sliding forks 510 and 520 may be slid by at least one of an LM guider, a ball screw and a belt or combinations of at least two thereof.

The second bi-directional sliding fork unit 340 may further include a position sensor to detect sliding positions of the sliding bars 514, 516 and 518 so as to control the second fork slider 530 when the sliding bars 514, 516 and 518 are slid in both directions.

As described above, the third and fourth sliding forks 510 and 520 of the second bi-direction sliding fork unit 340 are stretched or retracted so as to be simultaneously slid in the first conveyance direction or the second conveyance direction opposite to the first conveyance direction using the second slider 530, thereby transferring the substrates to the process chamber PC disposed at one side or the other side of the transfer chamber TC in both directions.

The fork elevation unit 350 in accordance with this embodiment includes a first elevation support 352a, a second elevation support 352b, a first elevation motor 354a, a second elevation motor (not shown), a first ball screw 356a, a second ball screw 356b, and an interlocking shaft 358.

The first elevation support 352a is vertically installed on the base frame 320 at the first side surface of the fork frame 320.

The second elevation support 352b is vertically installed on the base frame 310 at the second side surface of the fork frame 320 so as to face the first elevation support 352a.

The first elevation motor 354a is installed on the base frame 310 so as to be adjacent to the inner surface of the first elevation support 352a, thus rotating the first ball screw 356a in a first direction or a second direction opposite to the first direction.

The second elevation motor is installed on the base frame 310 so as to be adjacent to the inner surface of the second elevation support 352b, thus rotating the second ball screw 356b in the same direction as the first ball screw 356a.

The first ball screw 356a is installed between the first elevation support 352a and the first elevation motor 354a so as to pass through the protrusion 328 formed on the first support frame 322 of the fork frame 320, thus raising or lowering the first side of the fork frame 320 according to rotation of the first elevation motor 354a. Here, the protrusion 328 formed on the first support frames 322 is provided with a screw thread engaged with the first ball screw 356a.

The second ball screw 356b is installed between the second elevation support 352b and the second elevation motor so as to pass through the protrusion 328 formed on the first support frame 322 of the fork frame 320, thus raising or lowering the second side of the fork frame 320 according to rotation of the second elevation motor 354b. Here, the protrusion 328 formed on the first support frame 322 is provided with a screw thread engaged with the second ball screw 356b.

The interlocking shaft 358 is installed between the first elevation motor 354a and the second elevation motor and serves to transmit rotary force of one of the first elevation motor 354a or the second elevation motor to the other of the first elevation motor 354a or the second elevation motor, thereby interlocking rotation of the first elevation motor 354a and rotation of the second elevation motor so as to synchronize rotation of the first elevation motor 354a and rotation of the second elevation motor.

As described above, the fork elevation unit 350 raises or lowers the fork frame 320 according to rotation of the first and second ball screws 356a and 356b due to rotation of the first elevation motor 354a and the second elevation motor, thus raising or lowering the first and second bi-directional sliding fork units 330 and 340 to a desired height.

The fork elevation unit 350 may further include a position sensor to detect a position of the fork frame 320 when the fork frame 320 is raised or lowered so as to control rotation of the first elevation motor 354a and the second elevation motor.

The fork elevation guide unit 360 in accordance with this embodiment includes a plurality of elevation guide blocks 362 and a plurality of elevation guide rails 364.

The plural elevation guide blocks 362 are installed on the side wall support 324 corresponding to the corners of the first and second side surfaces of the fork frame 320. Here, two elevation guide blocks 362 may be installed on each of the first and second side surfaces of the fork frame 320.

The plural elevation guide rails 364 are vertically installed on the base frame 310 so as to be connected to the respective elevation guide blocks 362, thereby guiding raising or lowering of the respective elevation guide blocks 362 when the fork frame 320 is raised or lowered.

As described above, the substrate moving device may transfer substrates within the transfer chamber TC through horizontal transfer of the substrate transfer unit 200 and convey the substrates to the process chamber PC or the load lock chamber LC in both directions using the substrate conveyor unit 300.

Hereinafter, a substrate processing method of the above-described semiconductor manufacturing apparatus, i.e., a substrate moving method will be described.

First, plural substrates are sequentially loaded in the first chamber (the load lock chamber) provided with the alignment members. Here, the above-described alignment members in the load lock chamber align four corners of the plural substrates. Alignment of four substrates using rollers of the alignment members has been described above.

In addition to the alignment members provided at the corners of the substrates, other alignment members may be provided at a point where the plural substrates meet in the load lock chamber. When four substrates are provided within the load lock chamber, the latter alignment members may be a pair of alignment members having a rectilinear shape which cross each other at the center of the load lock chamber where the four substrates meet so as to align the four substrates in the horizontal and vertical directions.

Thereafter, the substrate conveyor unit conveys the plural substrates from the load lock chamber to the second chamber (the transfer chamber).

Thereafter, the substrate transfer unit transfers the substrates within the transfer chamber. Here, the substrate transfer unit transfers the substrates from a position parallel with the load lock chamber to a position parallel with the process chamber.

Thereafter, the substrate conveyor unit conveys the plural substrates from the transfer chamber to the third chamber (the process chamber). Here, the plural substrates are loaded in the process chamber in the same pattern as the aligned pattern in the load lock chamber.

The dividers may be provided in the process chambers. The dividers are provided in the same pattern as the alignment members, i.e., a pair of dividers having a rectilinear shape which cross each other, thereby aligning the four substrates in the horizontal and vertical directions.

Further, when the substrate conveyor unit conveys the substrates from an unloading chamber to a loading chamber, the substrate conveyor unit vertically raises the substrates in the unloading chamber, horizontally transfers the substrates from the unloading chamber to the loading chamber, and then vertically lowers and loads the substrates in the loading chamber.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A process chamber comprising:
a chamber body provided with a substrate entrance formed on a side surface thereof;
a substrate support provided within the chamber body such that at least two substrates are disposed on the substrate support; and
at least one divider provided within the chamber body to align the at least two substrates.

2. The process chamber according to claim 1, wherein each of the at least one divider includes a support member to support parts of the edges of the at least two substrates and a separation member contacting the at least two substrates to separate the at least two substrates from each other.

3. The process chamber according to claim 1, wherein the at least one divider includes a divider having a rectilinear shape to divide and align a pair of substrates facing each other, or includes two dividers having a rectilinear shape which cross each other to divide and align four substrates.

4. The process chamber according to claim 1, wherein the at least one divider has a line width of 4˜60 mm.

5. The process chamber according to claim 1, wherein the at least one divider aligns the at least two substrates at the same height.

6. The process chamber according to claim 1, wherein the at least one divider is formed of a ceramic or anodizing coated aluminum.

7. The process chamber according to claim 1, wherein the substrate support includes at least one of a loading frame to support the outermost regions of the lower surfaces of the at least two substrates and pins to support the central regions of the lower surfaces of the at least two substrates.

8. A semiconductor manufacturing apparatus comprising:
a transfer chamber provided with a substrate moving device to move substrates;
a load lock chamber to align the substrates and to load and unload the substrates into and out of the transfer chamber; and
at least one process chamber to process the substrates transferred from the transfer chambers,
wherein each of the at least one process chamber includes:
a chamber body provided with a substrate entrance formed on a side surface thereof;
a substrate support provided within the chamber body such that at least two substrates are disposed on the substrate support; and
at least one divider provided within the chamber body to align the at least two substrates.

9. The semiconductor manufacturing apparatus according to claim 8, further comprising alignment members provided in the load lock chamber to align the substrates.

10. The semiconductor manufacturing apparatus according to claim 9, wherein the alignment members are provided at least two corners of a support on which the substrates are seated.

11. The semiconductor manufacturing apparatus according to claim 8, wherein each of the at least one divider includes a support member to support parts of the edges of the at least two substrates and a separation member contacting the at least two substrates to separate the at least two substrates from each other.

12. The semiconductor manufacturing apparatus according to claim 8, wherein the at least one divider includes a divider having a rectilinear shape to divide and align a pair of substrates facing each other, or includes two dividers having a rectilinear shape which cross each other to divide and align four substrates.

13. The semiconductor manufacturing apparatus according to claim 10, wherein two substrates facing each other are provided within the load lock chamber, and the alignment members include stationary members or rotary members provided between the two substrates.

14. The semiconductor manufacturing apparatus according to claim 10, wherein four substrates are provided within the load lock chamber, and the alignment members include a pair of alignment members having a rectangular shape, crossing each other and provided at the center of the four substrates where the four substrates meet.

15. The semiconductor manufacturing apparatus according to claim 14, wherein the pair of alignment members includes at least four rotary members respectively provided between the four substrates and the four substrates are aligned by rotation of the rotary members.

16. The semiconductor manufacturing apparatus according to claim 14, wherein the alignment members within the load lock chamber and the at least one divider within the process chamber align the substrates in the same pattern.

17. The semiconductor manufacturing apparatus according to claim 16, wherein the at least one divider is formed of a ceramic or anodizing coated aluminum.

18. The semiconductor manufacturing apparatus according to claim 8, wherein the at least one divider aligns the at least two substrates at the same height.

19. A substrate processing method comprising:
sequentially loading at least two substrates into a first chamber provided with alignment members;
aligning corners of the at least two substrates using the alignment members;
conveying the at least two substrates from the first chamber to a second chamber using a substrate conveyor unit; and
conveying the at least two substrates from the second chamber to a third chamber using the substrate conveyor unit,
wherein the at least two substrates are loaded in the third chamber in the same pattern as an aligned pattern of the at least two substrates within the first chamber.

20. The substrate processing method according to claim 19, wherein at least one divider divides and aligns the at least two substrates at the same height by a predetermined interval within the third chamber.
